(19) United States
(12) Patent Application Publication
(10) Pub. No.: US 2009/0169790 A1
(43) Pub. Date: Jul. 2, 2009

(54) REINFORCED TUBE

(75) Inventors: Adam Paul Nadeau, Dracut, MA (US); Duan Li Ou, Northboro, MA (US); Mark W. Simon, Pascoag, RI (US); Anthony P. Pagliaro, JR., Landsale, PA (US); Anthony M. Diodati, Mullica Hill, NJ (US)

Correspondence Address: LARSON NEWMAN ABEL & POLANSKY, LLP, 5914 WEST COURTYARD DRIVE, SUITE 200, AUSTIN, TX, 78730, US

(73) Assignee: SAINT-GOBAIN PERFORMANCE PLASTICS CORPORATION, Aurora, OH (US)

(21) Appl. No.: 12/338,833

(22) Filed: Dec. 18, 2008

Related U.S. Application Data
(60) Provisional application No. 61/009,470, filed on Dec. 28, 2007.

(51) Int. Cl. B32B 1/08; C23C 16/00; B05D 3/10; B05D 3/00; B05D 3/06

(52) U.S. Cl. 428/36.91; 428/36.8; 427/255.28; 427/307; 427/534

(57) ABSTRACT

The disclosure is directed to a tube. The tube includes a silicone elastomer and at least one reinforcement member substantially embedded within the silicone elastomer. The disclosure is also directed to a tube including a first layer and a second layer adjacent the first layer. The first layer includes a fluoropolymer liner and the second layer includes a silicone elastomer and at least one reinforcement member substantially embedded within the silicone elastomer. This disclosure is further directed to a method for making the aforementioned tubes.

### CROSS-REFERENCE TO RELATED APPLICATION(S)

The present application claims priority from U.S. Provisional Patent Application No. 61/009,470, filed Dec. 28, 2007, entitled “REINFORCED TUBE”, naming inventors Adam Paul Nadeau, Duan Li Ou, Mark W. Simon, Anthony P. Pagliaro, Jr., and Anthony M. Diodati, which application is incorporated by reference herein in its entirety.

### FIELD OF DISCLOSURE

The invention relates generally to reinforced tubes and methods for making such tubes.

### BACKGROUND OF THE INVENTION

Biopharmaceutical companies invest in retaining the safety, sterility and operation of major capital equipment. Fluid connectors or tubing are used for the process flow from one equipment to another, for example, in steam-in-place or clean-in-place biopharmaceutical processes. Such processes require fluid connectors that can withstand high-pressured applications in, e.g., high temperature and/or caustic conditions and yet provide high purity and low extractables with excellent chemical and biological barrier performance properties.

Thus, it would desirable to provide both an improved tube as well as a method for manufacturing such a tube.

### BRIEF SUMMARY OF THE INVENTION

In a particular embodiment, a tube comprises a first layer comprising a fluoropolymer liner and a second layer adjacent the first layer. The second layer comprises a silicone elastomer and at least one reinforcement member substantially embedded within the silicone elastomer.

In another embodiment, a tube comprises a first layer comprising a fluoropolymer liner and a second layer adjacent the first layer. The second layer comprises a high consistency rubber silicone elastomer and a polyester braid substantially embedded within the silicone elastomer.

In another exemplary embodiment, a method of forming a multi-layer tube includes providing a fluoropolymer liner and providing a silicone elastomer cover over the fluoropolymer liner, the silicone elastomer cover including a reinforcement member substantially embedded within the silicone elastomer cover.

In a further exemplary embodiment, a method of forming a multi-layer tube includes providing a fluoropolymer liner and providing a high consistency rubber silicone elastomer cover over the fluoropolymer liner, the silicone elastomer cover including a polyester braid substantially embedded within the silicone elastomer cover.

In another embodiment, a tube comprises a silicone elastomer and at least one polyester reinforcement member substantially embedded within the silicone elastomer.

While multiple embodiments are disclosed, still other embodiments of the present invention will become apparent to those skilled in the art from the following detailed description. As will be apparent, the invention is capable of modifications in various obvious aspects, all without departing from the spirit and scope of the present invention. Accordingly, the detailed descriptions are to be regarded as illustrative in nature and not restrictive.

### BRIEF DESCRIPTION OF THE DRAWINGS

The present disclosure may be better understood, and its numerous features and advantages made apparent to those skilled in the art by referencing the accompanying drawings.

FIGS. 1 and 2 include illustrations of exemplary reinforced tubes.

FIG. 3 includes graphical illustrations of data representing the performance of tubes.

### DETAILED DESCRIPTION

In the specification and in the claims, the terms “including” and “comprising” are open-ended terms and should be interpreted to mean “including, but not limited to . . . ” These terms encompass the more restrictive terms “consisting essentially of” and “consisting of.”

In an embodiment, a tube includes an elastomer with at least one reinforcement member. In another embodiment, the reinforced tube includes a fluoropolymer liner and an elastomer with at least one reinforcement member. In a particular embodiment, the reinforced tube is a multi-layer tube that includes a fluoropolymer liner and a silicone elastomer with at least one polyester reinforcement member substantially embedded within the silicone elastomer. The fluoropolymer liner includes an inner surface that defines the central lumen of the tube. In an embodiment, the silicone elastomer includes high consistency rubber. In an exemplary embodiment, the high consistency rubber is self-bonding.

In an exemplary embodiment, the tube includes an elastomeric material. An exemplary elastomer may include cross-linkable elastomeric polymers of natural or synthetic origin. For example, an exemplary elastomeric material may include silicone, natural rubber, urethane, olefinic elastomer, diene elastomer, blend of olefinic and diene elastomer, fluoroelastomer, perfluoroelastomer, or any combination thereof.

In an exemplary embodiment, the elastomeric material is a silicone formulation. The silicone formulation may be formed, for example, using a non-polar silicone polymer. In an example, the silicone polymer may include polyalkylsiloxanes, such as silicone polymers formed of a precursor, such as dimethylsiloxane, diethylsiloxane, dipropylsiloxane, methylethylsiloxane, methylpropylsiloxane, or combinations thereof. In a particular embodiment, the polyalkylsiloxane includes a polydialkylsiloxane, such as polydimethylsiloxane (PDMS). In general, the silicone polymer is non-polar and is free of halide functional groups, such as chlorine and fluorine, and of phenyl functional groups. Alternatively, the silicone polymer may include halide functional groups or phenyl functional groups. For example, the silicone polymer may include fluorosilicone or phenylsilicone.

In an embodiment, the silicone polymer is a platinum catalyzed silicone formulation. Alternatively, the silicone polymer may be a peroxide catalyzed silicone formulation. In a further embodiment, the silicone polymer is a platinum and peroxide catalyzed silicone formulation. The silicone polymer may be a liquid silicone rubber (LSR) or a high consistency gum rubber (HCR). In a particular embodiment, the silicone polymer is a platinum catalyzed LSR. In a further embodiment, the silicone polymer is an LSR formed from a two part reactive system. Particular embodiments of LSR include Wacker 3003 by Wacker Silicone of Adrian, Mich. and Rhodia 4360 by Rhodia Silicones of Ventura, Calif. In another example, the silicone polymer is an HCR, such as GE 94506 HCR available from GE Plastics. In a particular embodiment, the silicone polymer is a peroxide catalyzed HCR.

When the elastomeric material is a silicone elastomer, the shore A durometer (Shore A) of the silicone polymer may be less than about 75, such as about 20 to about 50, such as about 30 to about 50, or about 40 to about 50.

In an embodiment, self-bonding silicone polymers may be used. Self-bonding silicone polymers typically have improved adhesion to substrates compared to conventional silicones. Particular embodiments of self-bonding silicone polymers include GE LIMS 8040 available from GE Plastics and KE2090-40 available from Shin-Etsu.

In an embodiment, an adhesion promoter may be used to impart self-bonding properties to the silicone elastomer. In an embodiment, the adhesion promoter includes silanes, an amine-containing alkyltrialkoxysilane, or silsesquioxanes. The term “silsesquioxane” as used herein is known in the art and is a generic name showing a compound in which each silicon atom is bonded to three oxygen atoms and each oxygen atom is bonded to two silicon atoms. In the present invention, this term is used as a general term of a silsesquioxane structure. In an embodiment, the adhesion promoter can include R₂SiO_{2/2} units, R₃SiO_{1/2} units and SiO_{4/2} units, wherein R is an alkyl radical, alkoxy radical, phenyl radical, or any combination thereof. In an embodiment, the silsesquioxane can include pre-hydrolyzed silsesquioxane prepolymers, monomers, or oligomers.

The silsesquioxane may be an “amine-containing silsesquioxane” and is intended to include silicon containing materials of the formula RSiO_{3/2} wherein R is an alkyl group that includes an amine (amino) functionality. In particular, the R group can be terminated with amine functionality. Suitable R groups include C1 through C6 hydrocarbon chains that can be branched or unbranched. Examples of suitable hydrocarbon chains, are for example but not limited to, methyl, ethyl, or propyl groups. Typically, the amine-containing silsesquioxane has an amine-containing alkyl content of at least about 30.0% by weight.

Commercial suppliers of suitable amine-containing silsesquioxanes include Momentive and Degussa. Examples of commercial products include SF1706 (Momentive), Hydrosil® 1151 (aminopropyl silsesquioxane), Hydrosil®2627 (aminopropyl co alkyl silsesquioxane), Hydrosil®2776, Hydrosil®2909 and Hydrosil®1146 (Degussa).

In an embodiment, the adhesion promoter is an amine-containing alkyltrialkyoxysilane. Commercial suppliers of suitable amine-containing alkyltrialkoxysilanes include Momentive, Dow Corning, and Degussa. Examples of commercial products include Silquest®1100 (Momentive), Dynasylan® AMMO, Dynasylan® AMEO, Dynasylan® DAMO (Degussa); Z-6011 silane and Z6020 silane (Dow Corning).

In addition, the silsesquioxane or silane can have desirable processing properties, such as viscosity. In particular, the viscosity can provide for improved processing in situ, such as during formulation mixing or extrusion. For example, the viscosity of the silsesquioxane or silane can be about 1.0 centistokes (cSt) to about 8.0 cSt, such as about 2.0 cSt to about 4.0 cSt, or about 3.0 cSt to about 7.0 cSt. In an example, the viscosity of the silsesquioxane or silane can be up to about 100.0 cSt, or even greater than about 100.0 cSt.

In a further embodiment, the adhesion promoter may include an ester of unsaturated aliphatic carboxylic acids. Exemplary esters of unsaturated aliphatic carboxylic acids include C1 to C8 alkyl esters of maleic acid and C1 to C8 alkyl esters of fumaric acid. In an embodiment, the alkyl group is methyl or ethyl. In an example, the maleic acid is an ester having the general formula:

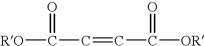

wherein R′ is a C1 to C8 alkyl group. In an embodiment, R′ is methyl or ethyl. In a particular embodiment, the adhesion promoter is dimethyl maleate, diethyl maleate, or any combination thereof.

In an embodiment, one or more of the above-mentioned adhesion promoters may be added to the silicone formulation. For instance, the adhesion promoter may include a mixture of the silsesquioxane and the ester of the unsaturated aliphatic carboxylic acid. In an embodiment, the silsesquioxane is an organosilsesquioxane wherein the organo group is a C1 through C18 alkyl. In an embodiment, the adhesion promoter is a mixture of the organosilsesquioxane and diethyl maleate. In another embodiment, the adhesion promoter is a mixture of the organosilsesquioxane and dimethyl maleate. In a particular embodiment, the mixture of the organosilsesquioxane and the ester of unsaturated aliphatic carboxylic acid is a weight ratio of about 1.5:1.0 to about 1.0:1.0.

Generally, the adhesion promoter is present in an effective amount to provide an adhesive formulation which bonds to substrates; it is self bonding. In an embodiment, an “effective amount” is about 0.1 weight % to about 5.0 weight %, such as about 1.0 wt % to about 3.0 wt %, or about 0.2 wt % to about 1.0 wt %, or about 0.5 wt % to about 1.5 wt % of the total weight of the elastomer.

Typically, the addition of the silsesquioxane adhesion promoter to the composition is detectable using nuclear magnetic resonance (NMR). The ²⁹Si NMR spectra of the silicon formulation has two groups of distinguished peaks at about −53 ppm to about −57 ppm and about −62 ppm to about −65 ppm, which corresponds to RSiO_{2/2} (OH) units and RSiO_{3/2} units, respectively.

The compositions containing the adhesion promoter exhibit improved adhesion to substrates. Typical substrates include polymeric materials such as thermoplastics and thermosets. An exemplary polymeric material can include polyamide, polyaramide, polyimide, polyolefin, polyvinylchloride, acrylic polymer, diene monomer polymer, polycarbonate (PC), polyetheretherketone (PEEK), fluoropolymer, polyester, polypropylene, polystyrene, polyurethane, polymeric ethyl vinyl alcohol (EVOH), polyvinylidene fluoride (PVDF), thermoplastic blends, or any combination thereof. Further polymeric materials can include silicones, phenolics, epoxys, or any combination thereof. In a particular embodiment, the substrate includes fluoropolymer, polyester, or any combination thereof.

In an embodiment, the substrate may be a polymeric material with reactive functionality. The phrase “polymeric material with reactive functionality” as used herein is intended to include substrates that inherently have functionality or can be treated by methods known in the art to impart functionality, such as a hydroxyl group, an amine group, a carboxyl group, a radical, etc. such that an interaction can occur between the adhesion promoter and at least the surface of the substrate. For example, polymeric ethyl vinyl alcohol (EVOH) includes hydroxyl groups throughout the polymeric structure that can react with the adhesion promoter. The self-bonding composition then can further react with a substrate that includes a group suitable for attachment, such as a hydroxyl group, an amine, a carboxylic acid, etc. In another embodiment, thermoplastic polyurethanes have residual isocyanates that can react with the amine functionality of the adhesion promoter, while the adhesion promoter can then further react with a hydroxyl on the surface of a substrate.

In an embodiment, the substrate is a reinforcement member. In a particular embodiment, the substrate is a silicone polymer that includes the reinforcement member substantially embedded within the silicone elastomer. In a particular embodiment, the reinforcement member may be polyester, adhesion modified polyester, polyamide, polyaramid, stainless steel, or combination thereof. In an exemplary embodiment, wherein the reinforcement member is polyester, the polyester is braided wherein strands of polyester yarn are intertwined. In an exemplary embodiment, wherein the reinforcement member is stainless steel, the stainless steel is helical wrapped stainless steel wire. In an embodiment, the reinforcement member is a combination of braided polyester and helical wrapped stainless steel wire. “Substantially embedded” as used herein refers to a reinforcement member wherein at least 25%, such as at least about 50%, or even 75% of the total surface area of the reinforcement member is directly in contact with the silicone elastomer.

In an example, the substrate is a fluoropolymer. In an embodiment, the fluoropolymer may be formed of a homopolymer, copolymer, terpolymer, or polymer blend formed from a monomer, such as tetrafluoroethylene, hexafluoropropylene, chlorotrifluoroethylene, trifluoroethylene, vinylidene fluoride, vinyl fluoride, perfluoropropyl vinyl ether, perfluoromethyl vinyl ether, or any combination thereof. For example, the fluoropolymer is polytetrafluoroethylene (PTFE). In an embodiment, the polytetrafluoroethylene (PTFE) can be paste extruded, skived, expanded, biaxially stretched, or an oriented polymeric film. In a further embodiment, the PTFE is non-fibrillated. “Non-fibrillated” as used herein refers to a structure that does not contain fibrils. In an exemplary embodiment, the fluoropolymer is a heat-shrinkable polytetrafluoroethylene (PTFE). The heat-shrinkable PTFE of the disclosure has a stretch ratio, defined as the ratio of the stretched dimension to the unstretched dimension, of not greater than about 4:1, such as not greater than about 3:1, not greater than about 2.5:1, or not greater than about 2:1. In an example, the heat-shrinkable PTFE may be uniaxially stretched. Alternatively, the heat-shrinkable PTFE may be biaxially stretched. In particular, the stretch ratio may be between about 1.5:1 and about 2.5:1. In an exemplary embodiment, the heat-shrinkable PTFE is not stretched to a node and fibril structure. In contrast, expanded PTFE is generally biaxially expanded at ratios of about 4:1 to form node and fibril structures. Hence, the heat-shrinkable PTFE of the disclosure maintains chemical resistance as well as achieves flexibility. In an embodiment, the heat-shrinkable PTFE has a tensile modulus at 100% elongation of less than about 3000 psi, such as less than about 2500 psi, or less than about 2000 psi.

In an embodiment, the fluoropolymer has high flex. High flex PTFE, such as Zeus' high flex PTFE product, maintains flexure as well as maintains chemical resistance. Further, high flex PTFE is not stretched to a node and fibril structure. Using M.I.T. folding/flex endurance, a high flex PTFE typically has a flex cycle greater than 3.0 million cycles, such as greater than 4.0 million cycles, such as greater than 5.0 million cycles, such as greater than 6.0 million cycles, or even greater than 6.5 million cycles when tested with a load of 4.5 lbs. Heat-shrinkable PTFE has a flex cycle greater than 3.0 million cycles, such as greater than 4.0 million cycles, such as greater than 5.0 million cycles, or even greater than 5.5 million cycles when tested with a load of 4.5 lbs. In contrast, the standard PTFE such as Zeus' standard PTFE product has a flex cycle of less than about 2.5 million cycles when tested with a load of 4.0 lbs. Further, heat-shrinkable PTFE with a stretch ratio of about 4:1 has a flex cycle of less than about 2.0 million cycles when tested with a load of 4.5 lbs.

Further exemplary fluoropolymers include a fluorinated ethylene propylene copolymer (FEP), a copolymer of tetrafluoroethylene and perfluoropropyl vinyl ether (PFA), a copolymer of tetrafluoroethylene and perfluoromethyl vinyl ether (MFA), a copolymer of ethylene and tetrafluoroethylene (ETFE), a copolymer of ethylene and chlorotrifluoroethylene (ECTFE), polychlorotrifluoroethylene (PCTFE), poly vinylidene fluoride (PVDF), a terpolymer including tetrafluoroethylene, hexafluoropropylene, and vinylidenefluoride (THV), or any blend or any alloy thereof. For example, the fluoropolymer may include FEP. In a further example, the fluoropolymer may include PVDF. In an exemplary embodiment, the fluoropolymer may be a polymer crosslinkable through radiation, such as e-beam. An exemplary crosslinkable fluoropolymer may include ETFE, THV, PVDF, or any combination thereof. A THV resin is available from Dyneon 3M Corporation Minneapolis, Minn. An ECTFE polymer is available from Ausimont Corporation (Italy) under the trade name Halar. Other fluoropolymers used herein may be obtained from Daikin (Japan) and DuPont (USA). In particular, FEP fluoropolymers are commercially available from Daikin, such as NP-12X .

In an embodiment, the fluoropolymer liners are paste extruded as opposed to mandrel wrapped. Paste extrusion is a process that typically includes extruding a paste of a lubricant and a fluoropolymer powder. In an example, the fluoropolymer powder is a fine PTFE powder fibrillated by application of shearing forces. This paste is extruded at low temperature (e.g., not exceeding 75° C.). In an embodiment, the paste is extruded in the form of a tube to form the liner. Once the paste is extruded, the PTFE may be stretched to a ratio of less than about 4:1 to form heat shrinkable PTFE. In particular, the heat-shrinkable PTFE may be uniaxially stretched by inflating the paste-extruded tube.

In contrast, expanded PTFE is typically formed on a mandrel. Typically, sheets of PTFE are expanded, such as biaxially stretching, and then wrapped around the mandrel. Due to the node and fibril structure of expanded PTFE, fluoroplastic sheets may be alternated and wrapped with the sheets of expanded PTFE. Subsequently, the mandrel is heated to a temperature sufficient to bond the multiple layers together and produce an expanded PTFE liner.

In an example, the heat-shrinkable PTFE liners have advantageous physical properties, such as desirable elongation-at-break. Elongation-at-break of the liner is the measure of elongation until the liner fails (i.e., breaks). In an exemplary embodiment, the liner may exhibit an elongation-at-break based on a modified ASTM D638 Type 5 specimen testing methods of at least about 250%, such as at least about 300%, or at least about 400%.

In general, the self-bonding formulation including the adhesion promoter exhibits desirable adhesion to a substrate without further treatment of the substrate surface. Alternatively, the substrate can be treated to further enhance adhesion. In an embodiment, the adhesion between the substrate and the self-bonding composition can be improved through the use of a variety of commercially available surface treatments of the substrate. An exemplary surface treatment can include chemical etch, physical-mechanical etch, plasma etch, corona treatment, chemical vapor deposition, or any combination thereof. In an embodiment, the chemical etch includes sodium ammonia and sodium naphthalene. An exemplary physical-mechanical etch can include sandblasting and air abrasion. In another embodiment, plasma etching includes reactive plasmas such as hydrogen, oxygen, acetylene, methane, and mixtures thereof with nitrogen, argon, and helium. Corona treatment can include the reactive hydrocarbon vapors such as acetone. In an embodiment, the chemical vapor deposition includes the use of acrylates, vinylidene chloride, and acetone. Once the article is formed, the article can be subjected to a post-cure treatment, such as a thermal treatment or radiative curing. Thermal treatment typically occurs at a temperature of about 125° C. to about 200° C. In an embodiment, the thermal treatment is at a temperature of about 150° C. to about 180° C. Typically, the thermal treatment occurs for a time period of about 5 minutes to about 10 hours, such as about 10 minutes to about 30 minutes, or alternatively about 1 hour to about 4 hours.

In an embodiment, radiation crosslinking or radiative curing can be performed once the article is formed. The radiation can be effective to crosslink the self-bonding composition. The intralayer crosslinking of polymer molecules within the self-bonding composition provides a cured composition and imparts structural strength to the composition of the article. In addition, radiation can effect a bond between the self-bonding composition and the substrate, such as through interlayer crosslinking. In a particular embodiment, the combination of interlayer crosslinking bonds between the substrate and the self-bonding composition present an integrated composite that is highly resistant to delamination, has a high quality of adhesion resistant and protective surface, incorporates a minimum amount of adhesion resistant material, and yet, is physically substantial for convenient handling and deployment of the article. In a particular embodiment, the radiation can be ultraviolet electromagnetic radiation having a wavelength between 170 nm and 400 nm, such as about 170 nm to about 220 nm. In an example, crosslinking can be effected using at least about 120 J/cm² radiation.

In an exemplary embodiment, the self-bonding composition advantageously exhibits desirable peel strength when applied to a substrate. In particular, the peel strength can be significantly high or the layered structure can exhibit cohesive failure during testing. “Cohesive failure” as used herein indicates that the self-bonding composition or the substrate ruptures before the bond between the self-bonding composition and the substrate fails. In an embodiment, the article has a peel strength of at least about 0.9 pounds per inch (ppi), or even enough to lead to cohesive failure, when tested in standard “180°”-Peel configuration at room temperature prior to any post-cure, or can have a peel strength of at least about 10.0 ppi after post-cure treatment when adhered to a polymeric substrate. For example, before post-cure treatment, the self-bonding composition can exhibit a peel strength of at least about 0.6 ppi, such as at least about 4.0 ppi, or even at least about 10.0 ppi, when adhered to polycarbonate. After treatment, the self-bonding composition can exhibit a peel strength of at least about 10.0 ppi, such as at least about 16.0 ppi, or even cohesively fail during the test when adhered to EVOH (ethylene vinyl alcohol resin). In another example, the peel strength of the article can be at least about 2.0 ppi, such as at least about 7.0 ppi, at least about 13.0 ppi, or even enough to lead to cohesively fail during testing when the substrate is PVDF and prior to any post-cure. When the substrate is polyetheretherketone, the article can have a peel strength of at least about 2.9 ppi, such as at least about 8.0 ppi, such as at least about 12.0 ppi, or even enough to lead to cohesively fail during testing after post-cure treatment. When the substrate is polyester, the article can have a peel strength of at least about 0.8 ppi, such as about 22.0 ppi or even cohesively fail prior to any post-cure. After treatment, the self-bonding composition can exhibit a peel strength of at least about 65.0 ppi, or even cohesively fail during the test when adhered to polyester.

In addition to desirable peel strength, the self-bonding compositions have advantageous physical properties, such as improved elongation-at-break, tensile strength, or tear strength. Elongation-at-break and tensile strength are determined using an Instron instrument in accordance with ASTM D-412 testing methods. For example, the self-bonding composition can exhibit an elongation-at-break of at least about 350%, such as at least about 500%, at least about 550%, or even at least about 650%. In an embodiment, the tensile strength of the self-bonding composition is greater than about 400 psi, and in particular, is at least about 1100 psi, such as at least about 1200 psi. Particular embodiments exhibit a desirable combination of elongation and tensile strength, such as exhibiting a tensile strength of at least about 800 psi and an elongation of at least about 500%. Further, the self-bonding composition can have a tear strength greater than about 100 ppi, such as at least about 225 ppi, or even at least about 300 ppi.

The self-bonding formulation can be used to form any useful articles such as monolayer articles, multilayer articles, or can be laminated, coated, or formed on a substrate. In an example, the self-bonding formulation can be used to form a multilayer film or tape. The self-bonding formulation can be used as a film or tape to provide a barrier layer or a chemical resistant layer. Alternatively, the self-bonding formulation can be used to form an irregularly shaped article. To form a useful article, the polymeric substrate can be processed. Processing of the polymeric substrate, particularly the thermoplastic substrates, can include casting, extruding or skiving. Processing of the self-bonding composition can include any suitable method such as compression molding, overmolding, liquid injection molding, extrusion, coating, or processing as a thin film.

In an embodiment, the self-bonding formulation can be used to produce a tube. A tube is an elongated annular structure with a hollow central bore. For instance, the self-bonding formulation can be used to produce a tube having the reinforcement member substantially embedded therein. The tube of the self-bonding formulation with the reinforcement member has advantageous physical properties such as a desirable low percentage of extractable total organic contents (TOC) contained in the stream extract and well as desirable burst pressure. In particular, a self-bonding silicone elastomer containing the reinforcing polyester braid can provide a TOC of less than about 1.5 ppm. In a further embodiment, in combination with a fluoropolymer liner, the self-bonding silicone elastomer containing the reinforcing polyester braid can provide a TOC of much less than about 1.5 ppm, such as less than about 1.0 ppm, such as even less than about 0.5 ppm. The burst pressure of an embodiment is dependent on whether the tube is lined with or without fluoropolymer and the size of the diameter of the tube. In an embodiment, the burst pressure of an unlined tube is about 750 psi to about 375 psi for a tube having about 0.25″ I.D. (inner diameter) to about 1.00″ I.D.

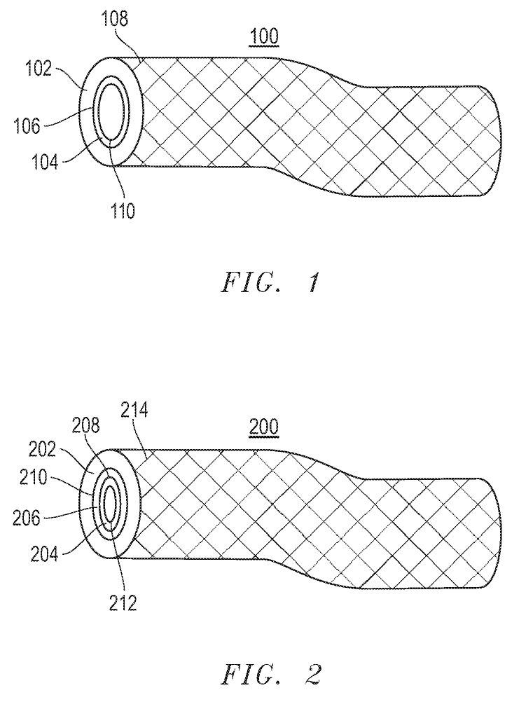

As illustrated in FIG. 1, a liner, and a cover are used to produce a multi-layer tube 100. The multi-layer tube 100 is an elongated annular structure with a hollow central bore. The multi-layer tube 100 includes a cover 102 and a liner 104. The cover 102 is directly in contact with and may be directly bonded to a liner 104 along an outer surface 106 of the liner 104. For example, the cover 102 may directly bond to the liner 104 without intervening adhesive layers. In an exemplary embodiment, the multi-layer tube 100 includes at least two layers, such as the cover 102 and the liner 104. A reinforcement member 108 is substantially embedded in the cover 102. In an exemplary embodiment, the liner 104 is a fluoropolymer. In an embodiment, the reinforcement member 108 is a braided polyester. In another embodiment, the reinforcement member 108 is a braided polyester with a thin metal wire. In an embodiment, the cover 102 includes a silicone elastomer or a high consistency rubber silicone elastomer or a liquid silicone elastomer. In a particular embodiment, the high consistency rubber silicone elastomer or the liquid silicone elastomer is self bonding. In a further embodiment, the cover 102 including the reinforcement member 108 is covered by a second silicone elastomer layer (not shown) that may be mandrel wrapped. The liner 104 includes an inner surface 110 that defines a central lumen of the tube 100. In an even further embodiment, the multi-layer tube may include four or more layers. For example, in this multi-layer tube 100, a second reinforcement member may be substantially embedded in the second silicone elastomer layer, which may further include a third silicone elastomer layer over the second reinforcement member. Each silicone elastomer layer may be mandrel wrapped, extruded, or extruded over a mandrel.

Alternatively, a multi-layer tube 200 as illustrated in FIG. 2 may include three or more layers. The multi-layer tube 200 includes a cover 202 and a liner 204. For example, FIG. 2 illustrates a third layer 206 sandwiched between liner 204 and cover 202. In an exemplary embodiment, third layer 206 is directly in contact with and may be directly bonded to the outer surface 208 of the liner 204. In such an example, the third layer 206 may directly contact and may be bonded to cover 202 along an outer surface 210 of third layer 206. In an embodiment, the third layer 206 may be an adhesive layer. The liner 204 includes an inner surface 212 that defines a central lumen of the tube 200. The tube 200 further includes a reinforcement member 214 substantially embedded in the cover 202.

Returning to FIG. 1, the multi-layer tube 100 may be formed through a method wherein the elastomeric cover 102 is extruded over the liner 104. In an embodiment, the elastomeric cover 102 may be mandrel wrapped or extruded over a mandrel. The liner 104 includes an inner surface 110 that defines a central lumen of the tube. In an exemplary embodiment, the liner 104 may be a paste-extruded fluoropolymer. Paste extrusion is a process that includes extruding a paste of a lubricant and a PTFE powder. Typically, the PTFE powder is a fine powder fibrillated by application of shearing forces. This paste is extruded at low temperature (not exceeding 75° C.). In an embodiment, the paste is extruded in the form of a tube. Once the paste is extruded, the PTFE may be stretched to a ratio of less than about 4:1 to form heat shrinkable PTFE. In an embodiment, the multi-layer tube 100 may be produced without the use of a mandrel during the laminating process, and the heat-shrink PTFE liner is produced without mandrel wrapping. In an embodiment, the total thickness of the liner 104 may be from about 1 mil to about 30 mils, such as about 1 mil to about 20 mils, such as about 3 mils to about 10 mils, or about 1 mil to about 2 mils.

Prior to extrusion of the cover 102, adhesion between the liner 104 and the cover 102 may be improved through the use of a surface treatment of the outer surface 106 of the liner 104. In an embodiment, radiation crosslinking may be performed once the multi-layer tube 100 is formed. Further, the liner 104 may be pressurized at a pressure of about 5 psi to about 40 psi during the entire extrusion process to increase adhesion.

In an embodiment, the cover 102 is co-extruded with the reinforcement member 108. Prior to co-extrusion of the cover 102 and the reinforcement member 108, adhesion between the cover 102 and the reinforcement member 108 may be improved through the use of a heat treatment of the reinforcement member 108. In an embodiment, the reinforcement member 108 may be heated to substantially remove any excess moisture on the reinforcement member 108. “Substantially remove any excess moisture” as used herein refers to heating for a sufficient time and at a sufficient temperature to remove at least about 95%, such as 99% moisture from, for example, the polyester braid. In an embodiment, the heat treatment is for a time period of about 45 minutes to about 240 minutes at a temperature of about 225° F. to about 350° F. In an embodiment, the cover 102 is extruded over a mandrel or mandrel wrapped such that the reinforcement member 108 is substantially embedded within the cover 102.

In general, the cover 102 has greater thickness than the liner 104. The total tube thickness of the tube 100 may be at least about 3 mils to about 50 mils, such as about 3 mils to about 20 mils, or about 3 mils to about 10 mils. In an embodiment, the liner 104 has a thickness of about 1 mil to about 20 mils, such as about 3 mils to about 10 mils, or about 1 mil to about 2 mils.

Also generally, the tube 100 also has an inner diameter of about 0.25 inches to about 4.00 inches, or about 0.25 inches to about 1 inch.

In an exemplary embodiment, the multi-layer tube advantageously exhibits desirable burst pressure. In an embodiment, the multi-layer tube generates a burst pressure of greater than about 270.0 psi, such as greater than about 300.0 psi, such as greater than about 500.0 psi, such as greater than about 900.0 psi, such as greater than about 1000.0 psi, or even greater than about 1050.0 psi. In a further exemplary embodiment, the burst pressure of a fluoropolymer lined tube is about 1050 psi to about 500 psi for a tube having about 0.25″ I.D. to about 1.00″ I.D.

Once formed and cured, particular embodiments of the above-disclosed multi-layer tube advantageously exhibit desired properties such as increased lifetime and flow stability. For example, the multi-layer tube may have a pump life of greater than about 250 hours, such as greater than about 350 hours. In an embodiment, a multi-layer tube including a liner formed of a heat-shrinkable fluoropolymer is particularly advantageous, providing improved lifetime. In a further embodiment, a liner formed of a sodium-napthalene etched heat-shrinkable fluoropolymer is particularly advantageous, reducing delamination of the liner and the coating.

In an exemplary embodiment, the multi-layer tube may have less than about 30% loss in the delivery rate when tested for flow stability. In particular, the loss in the delivery rate may be less than about 60%, such as less than about 40%, or such as less than about 30%, when tested at 600 rpm on a standard pump head.

The invention will be further described with reference to the following non-limiting Examples. It will be apparent to those skilled in the art that many changes can be made in the embodiments described without departing from the scope of the present invention. Thus the scope of the present invention should not be limited to the embodiments described in this application, but only by embodiments described by the language of the claims and the equivalents of those embodiments. Unless otherwise indicated, all percentages are by weight.

### EXAMPLE 1

The following results were generated in the preparation of a 0.375 inch ID (inner diameter) multi-layer reinforced tube of the invention. All test samples were built in accordance with standard manufacturing procedures previously developed and in accordance with the processing conditions referenced hereinabove. Generally, the hose test samples were made in the standard three-step process. First, the core tubing was extruded and cured in vertical or horizontal tower ovens. This can either be jacketing of a fluoropolymer liner with a layer of silicone or it could be extruding an all silicone core. As a second step, the core tubing was braided with the reinforcement member, with an option for drying in an oven, for example, at a temperature of about 225° F. to about 350° F. for a time period of about 45 minutes to about 240 minutes before the third step. In the third step, a layer of silicone was extruded on top of the braided core tubing. This multi-layer construction was then post-cured in an oven to completely cure the silicone, promoting additional bonding between all of the materials in the tubing. Once post-cure was complete, samples were connected with proper fittings for testing.

TABLE 1
Burst Pressure, psi (pounds per square inch)

| Control | ST65-SB | | | |
|---|---|---|---|---|
| (unlined) | (unlined) | PTFE | PFA | FEP |
| 620 | 291 | 615 | 493 | 474 |
| 620 | 288 | 684 | 558 | 540 |
| 617 | 365 | 748 | 526 | 542 |
| 625 | 306 | 602 | 484 | 491 |
| 622 | 281 | 628 | 499 | 503 |
| 636 | 290 | 658 | 495 | 493 |
| 615 | 298 | 636 | 494 | 568 |
| 628 | 266 | 631 | 510 | 530 |

As shown in TABLE 1, for the CONTROL (ID=0.385″, OD=0.615), this was a standard STHT but with a polyester braid and unlined, having a minimum bend radius (MBR) of 1.5 inches, vacuum performance was held for 3 minutes at 29 Hg. Vacuum at MBR had resulted in deformation of the hose live length in 1.5 minutes at 10 Hg. Crimp diameter was about 0.7455″.

For ST65-SB (ID=0.382″, OD=0.617″) MBR-1½″, this sample was made using a self-bonding Sanitech 65 with a polyester braid. Vacuum was held for 2 minutes at 17 Hg. Vacuum at MBR had resulted in total collapse after 25 seconds. Crimp Diameter was about 0.7460″.

For PTFE (ID=0.330″, OD=0.615″) MBR-1¾″, this sample was made using a liner from Zeus and etched at Acton Technologies, ST65-SB silicone and polyester braid. Vacuum was applied for 5 minutes at 29 Hg. Vacuum at MBR caused slight deformation after 2.5 minutes at 29 Hg. Crimp Diameter was about 0.7750″.

For PFA (ID=0.331″, OD=0.610″) MBR-1¾″, this liner was extruded and etched in Mickleton using ST65-SB silicone and polyester braid. Vacuum was applied for 5 minutes at 29 Hg. Vacuum at MBR caused slight deformation at radius arc. Crimp Diameter=0.7575″.

For FEP (ID=0.343″, OD=0.624″) MBR-1¾″, this sample was made using a liner that was extruded and etched in Mickleton. ST65-SB silicone and polyester braid was used. Vacuum was applied for 5 minutes at 29 Hg. Vacuum at MBR caused a kink in the hose at the radius arc center after 2 minutes.

### EXAMPLE 2

The following results were generated by the preparation and testing of a 0.25 inch ID (inner diameter) multi-layer reinforced tube of the invention. All test samples were built in accordance with standard manufacturing procedures previously developed and described in EXAMPLE 1.

TABLE 2
Control sample

| | Bend | Vacuum | Radius/Vac | Growth/ | |
|---|---|---|---|---|---|
| Sample | Radius (in.) | (Hg in.) | (Hg in.) | Pres (in.) | Burst (psi) |
| 1 | 1 | 29.9 | 29.9 | 0.5 | 693 |
| 2 | 1 | 29.9 | 29.9 | 0.5 | 746 |
| 3 | 1 | 29.9 | 29.9 | 0.5 | 810 |
| 4 | 1 | 29.9 | 29.9 | 0.5 | 848 |
| 5 | 1 | 29.9 | 29.9 | 0.5 | 796 |
| 6 | 1 | 29.9 | 29.9 | 0.5 | 739 |
| 7 | 1 | 29.9 | 29.9 | 0.5 | 733 |
| 8 | 1 | 29.9 | 29.9 | 0.5 | 815 |
| 9 | 1 | 29.9 | 29.9 | 0.5 | 813 |
| 10 | 1 | 29.9 | 29.9 | 0.5 | 790 |
| 11 | 1 | 29.9 | 29.9 | 0.5 | 719 |
| 12 | 1 | 29.9 | 29.9 | 0.5 | 773 |

TABLE 3
ST65-SB SAMPLE

| | Bend | Vacuum | Radius/Vac | Growth/ | |
|---|---|---|---|---|---|
| Sample | Radius (in.) | (Hg in.) | (Hg in.) | Pres (in.) | Burst (psi) |
| 1 | 1 | 29.9 | 29.9 | 0.75 | 909 |
| 2 | 1 | 29.9 | 29.9 | 0.75 | 899 |
| 3 | 1 | 29.9 | 29.9 | 0.75 | 836 |
| 4 | 1 | 29.9 | 29.9 | 0.75 | 895 |
| 5 | 1 | 29.9 | 29.9 | 0.75 | 853 |
| 6 | 1 | 29.9 | 29.9 | 0.75 | 798 |
| 7 | 1 | 29.9 | 29.9 | 0.75 | 817 |
| 8 | 1 | 29.9 | 29.9 | 0.75 | 893 |
| 9 | 1 | 29.9 | 29.9 | 0.75 | 888 |
| 10 | 1 | 29.9 | 29.9 | 0.75 | 790 |
| 11 | 1 | 29.9 | 29.9 | 0.75 | 865 |
| 12 | 1 | 29.9 | 29.9 | 0.75 | 898 |

TABLE 4
PTFE SAMPLE

| | Bend | Vacuum | Radius/Vac | Growth/ | |
|---|---|---|---|---|---|
| Sample | Radius (in.) | (Hg in.) | (Hg in.) | Pres (in.) | Burst (psi) |
| 1 | 1.25 | 29.9 | 29.9 | 0.0 | 969 |
| 2 | 1.25 | 29.9 | 29.9 | 0.0 | 963 |
| 3 | 1.25 | 29.9 | 29.9 | 0.0 | 1,079 |
| 4 | 1.25 | 29.9 | 29.9 | 0.0 | 980 |
| 5 | 1.25 | 29.9 | 29.9 | 0.0 | 1,146 |
| 6 | 1.25 | 29.9 | 29.9 | 0.0 | 986 |
| 7 | 1.25 | 29.9 | 29.9 | 0.0 | 975 |
| 8 | 1.25 | 29.9 | 29.9 | 0.0 | 1,208 |
| 9 | 1.25 | 29.9 | 29.9 | 0.0 | 1,150 |
| 10 | 1.25 | 29.9 | 29.9 | 0.0 | 1,174 |
| 11 | 1.25 | 29.9 | 29.9 | 0.0 | 1,066 |
| 12 | 1.25 | 29.9 | 29.9 | 0.0 | 987 |

TABLE 5
AVERAGES OF TABLES 2-4

| | | Growth @ | Burst | | |
|---|---|---|---|---|---|
| | Bend | Pressure | Pressure | Burst | Standard |
| Sample | Radius (in.) | (in.) | (psi) | (Std Dev) | Error |
| Control | 1 | 0.50 | 772.9 | 46.7 | 13.47751 |
| ST65-SB | 1 | 0.75 | 861.8 | 42.3 | 12.20725 |
| PTFE | 1.25 | 0.00 | 1,056.9 | 91.8 | 26.51456 |

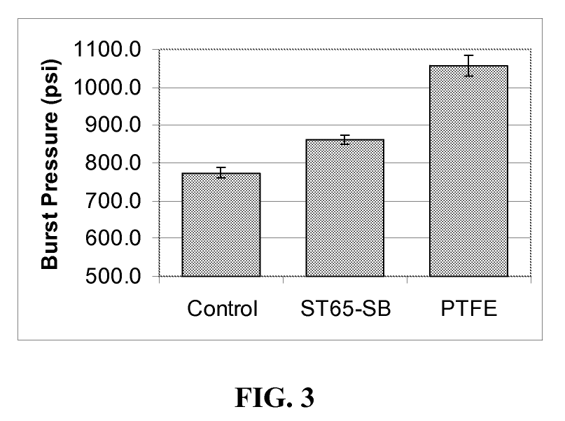

Indicative of the results generated in TABLE 5, as shown in FIG. 3, for an 0.25 inch ID multi-layered hose product, the control sample was an unlined standard STHT silicone hose but with a polyester braid. The ST65-SB sample was a self-bonding Sanitech 65 silicone hose with a polyester braid that was unlined. The PTFE sample was a self-bonding Sanitech 65 silicone hose lined with PTFE, also embedded with a polyester braid. As shown in FIG. 3, the PTFE lined sample had a 40% increase in burst pressure while having an MBR of 1.25″. The ST65-SB sample hose had a 15% increase in burst pressure while maintaining an MBR of 1.00″. All samples withstood the maximum vacuum pressure of 29.9 Hg for 5 minutes.

### EXAMPLE 3

The following results were generated by the preparation and testing of a 0.25 inch ID (inner diameter) multi-layer reinforced tube of the invention. All test samples were built in accordance with standard manufacturing procedures previously developed and described in EXAMPLE 1.

TABLE 6
Average of test results for 1″ ID hoses

| | | | Minimum | |
|---|---|---|---|---|
| | | | Bend Radius | |
| | Burst Pressure (psi) | | (in) | Vacuum (Hg in.) |
| Control-R | 252 | (10.2) | 6.0 | 10.0 |
| Control-WR | 334 | (8.0) | 4.0 | 29.9 |
| FEP-R | 387 | (6.7) | 7.5 | 15 |
| FEP-WR | 463 | (59.6) | 6.5 | 29.9 |

* Number denoted in parentheses ( ) is the Standard Error

The results generated for TABLE 6 were for 1.00 inch ID multi-layered hose samples. The Control-R sample was an unlined standard silicone hose that contained only a polyester braid. The Control-WR sample was an unlined standard silicone hose product that contained a polyester braid as well as a helical wrapped stainless steel wire. The FEP-R sample was a self-bonding Sanitech 65 silicone hose lined with PTFE, also embedded with a polyester braid. The FEP-WR sample was a self-bonding Sanitech 65 silicone hose lined with PTFE, also embedded with a polyester braid and a helical wrapped stainless steel wire. As shown in TABLE 6, the FEP-R has approximately a 50% increase in burst pressure over the Control-R sample, while the FEP-WR has approximately a 39% increase in burst pressure over the Control-WR sample. The FEP-R has a 50% increase in the vacuum stability compared to the Control-R sample while the Control-WR and FEP-WR samples reached the testing equipment's maximum setting. The FEP-R has approximately a 25% increase in minimum bend radius compared to the Control-R sample; while the FEP-WR has approximately a 60% increase in the minimum bend radius compared to the Control-WR sample.

Although the present invention has been described with reference to preferred embodiments, persons skilled in the art will recognize that changes may be made in form and detail without departing from the spirit and scope of the invention. All references cited throughout the specification, including those in the background, are incorporated herein in their entirety. Those skilled in the art will recognize, or be able to ascertain, using no more than routine experimentation, many equivalents to specific embodiments of the invention described specifically herein. Such equivalents are intended to be encompassed in the scope of the following claims.

1. A tube comprising;
a first layer comprising a fluoropolymer liner; and
a second layer adjacent the first layer, the second layer comprising a silicone elastomer and at least one reinforcement member substantially embedded within the silicone elastomer.

2. The tube of claim 1, wherein the reinforcement member is polyester, adhesion modified polyester, polyamide, polyaramid, stainless steel, or combinations thereof.

3. The tube of claim 2, wherein the reinforcement member is braided polyester.

4. The tube of claim 3, wherein the second layer further comprises a stainless steel wire.

5. (canceled)

6. The tube of claim 1, wherein the silicone elastomer includes high consistency rubber or liquid silicone rubber.

7. The tube of claim 6, wherein the silicone elastomer is self-bonding.

8. The tube of claim 1, wherein the fluoropolymer liner includes a fluoropolymer selected from the group consisting of a polytetrafluoroethylene (PTFE), fluorinated ethylene propylene copolymer (FEP), a copolymer of tetrafluoroethylene and perfluoropropyl vinyl ether (PFA), a copolymer of tetrafluoroethylene and perfluoromethyl vinyl ether (MFA), an ethylene tetrafluoroethylene copolymer (ETFE), an ethylene chlorotrifluoroethylene copolymer (ECTFE), polychlorotrifluoroethylene (PCTFE), polyvinylidene fluoride (PVDF), and a tetrafluoroethylene hexafluoropropylene vinylidene fluoride terpolymer (THV).

9.-12. (canceled)

13. The tube of claim 1, having a burst pressure of greater than about 270.0 psi.

14.-32. (canceled)

33. A method of forming a multi-layer tube comprising:
providing a fluoropolymer liner; and
providing a silicone elastomer cover over the fluoropolymer liner, the silicone elastomer cover including a reinforcement member substantially embedded within the silicone elastomer cover.

34. The method of claim 33, wherein the reinforcement member is polyester, adhesion modified polyester, polyamide, polyaramid, stainless steel, or combinations thereof.

35. (canceled)

36. The method of claim 33, wherein the fluoropolymer liner includes an outer surface, the method further comprising treating the outer surface prior to the step of providing the elastomeric cover.

37. The method of claim 36, wherein treating the outer surface includes chemical etching, physical-mechanical etching, plasma etching, corona treatment, chemical vapor deposition, or combinations thereof.

38. (canceled)

39. (canceled)

40. The method of claim 33, wherein the fluoropolymer liner is paste extruded prior to providing the silicone elastomer cover.

41. (canceled)

42. (canceled)

43. The method of claim 33, wherein providing the silicone elastomer cover includes extruding, mandrel wrapping, or extruding over a mandrel the silicone elastomer cover over the fluoropolymer liner.

44. The method of claim 43, further comprising applying pressure of about 5 psi to about 40 psi to the fluoropolymer liner during the step of extrusion.

45. (canceled)

46. (canceled)

47. The method of claim 33, wherein the silicone elastomer is co-extruded with the reinforcement member.

48. The method of claim 47, further comprising the step of heating the reinforcement member to a temperature of about 225° F. to about 350° F. prior to the step of co-extruding with the silicone elastomer.

49. (canceled)

50. The method of claim 33, further comprising heating the multi-layer tube to a temperature of about 125° C. to about 200° C.

51.-65. (canceled)

66. A tube comprising a silicone elastomer and at least one polyester reinforcement member substantially embedded within the silicone elastomer.

67. The tube of claim 66, having a TOC level of less than about 1.5 ppm.

68. The tube of claim 66, having a burst pressure of about 375 psi to about 750 psi.

69.-72. (canceled)

73. The tube of claim 66, wherein the polyester reinforcement member is braided.

74. The tube of claim 66, wherein the silicone elastomer further comprises an adhesion promoter.

75. The tube of claim 74, wherein the adhesion promoter includes a silane, a silsesquioxane, an ester of an unsaturated aliphatic carboxylic acid, or mixtures thereof.

76. The tube of claim 66, wherein the silicone elastomer is high consistency rubber or liquid silicone rubber.

77. (canceled)
